(19) United States
(12) Patent Application Publication
(10) Pub. No.: US 2023/0394188 A1
(43) Pub. Date: Dec. 7, 2023

(54) ARCHITECTURE FOR SMART BUILDINGS

(71) Applicant: Simple Things Inc., Palo Alto, CA (US)

(72) Inventors: James Zhang, Carlsbad, CA (US); Andrew Rubin, Woodside, CA (US); Volodymyr Ishchenko, kHARKIV (UA); Oleksii Parshyn, Kharkiv (UA); Joel Buchheim-Moore, San Francisco, CA (US); Jeffrey Regan, San Francisco, CA (US); Kristopher Linquist, Santa Clara, CA (US); Yateesh Chandraiah, San Jose, CA (US); Omer Akram, Multan (PK); Jean-Baptiste Theou, Séné (FR); Christopher Coley, Morgan Hill, CA (US); Kevin Hoffman, San Francisco, CA (US); Omar Puig, Santa Clara, CA (US); Sergei Kononov, Dublin, CA (US); Avinash Shetty, San Jose, CA (US); Mike Eynon, Woodside, CA (US)

(21) Appl. No.: 18/322,438

(22) Filed: May 23, 2023

Related U.S. Application Data
(60) Provisional application No. 63/365,983, filed on Jun. 7, 2022.

(51) Int. Cl. G06F 30/13

(52) U.S. Cl. CPC G06F 30/13

(57) ABSTRACT

A computer-implemented method for implementing an architecture for a smart building includes receiving, by a hub of the smart building, speech input from a smart speaker. The speech input describes asynchronous events associated with smart devices in the smart building. The hub is connected to a cloud Web Application Messaging Protocol (WAMP) router located in a cloud. The asynchronous events are converted to a trigger, a condition, or an action to be performed by at least one smart device. An automated flow is generated for controlling at least one adapter in the smart building from at least one of the trigger, the condition, or the action. The at least one adapter operates the at least one smart device. The at least one smart device corresponds to at least one node in the automated flow.

### CROSS-REFERENCE TO RELATED APPLICATION(S)

This application claims priority to and the benefit of U.S. Provisional Patent Application No. 63/365,983, filed on Jun. 7, 2022, which is incorporated by reference herein in its entirety.

### TECHNICAL FIELD

The present disclosure is generally related to smart devices that connect to a network for pairing smart home products for both convenience and safety.

### BACKGROUND

Traditional smart home gadgets, such as thermostats, security cameras, and sensors don't automatically work together. Conventional devices often each require a separate smartphone app. Further, network connectivity issues are often problematic, from smart cameras dropping the feed, to living room smart lights failing to turn off. Furthermore, security alerts are often triggered by false alarms from tree branches blowing in the wind or a cat jumping on furniture. Moreover, users experience difficulties in adapting to smart home technologies because they are confined to an app to control their homes. A single change to smart home gadgets can require a user to make that single change in multiple smartphone apps representing multiple smart home devices and sensors.

### BRIEF DESCRIPTION OF THE DRAWINGS

FIG. 1 is a block diagram illustrating an example smart device monitoring and control architecture for smart buildings, in accordance with one or more embodiments.

FIG. 2 is a drawing illustrating an example hub in an architecture for smart buildings, in accordance with one or more embodiments.

FIG. 3A is a drawing illustrating code for an example adapter for smart buildings, in accordance with one or more embodiments.

FIG. 3B is a block diagram illustrating example connectivity for an architecture for smart buildings, in accordance with one or more embodiments.

FIG. 4 is a drawing illustrating example microservices for an architecture for smart buildings, in accordance with one or more embodiments.

FIG. 5 is a flow diagram illustrating an example process for an architecture for smart buildings, in accordance with one or more embodiments.

FIG. 6 is a block diagram illustrating an example machine learning system, in accordance with one or more embodiments.

FIG. 7 is a block diagram illustrating an example computer system, in accordance with one or more embodiments.

### DETAILED DESCRIPTION

Embodiments of the present disclosure will be described more thoroughly from now on with reference to the accompanying drawings. Like numerals represent like elements throughout the several figures, and in which example embodiments are shown. However, embodiments of the examples can be embodied in many different forms and should not be construed as limited to the embodiments set forth herein. The examples set forth herein are non-limiting examples and are merely examples, among other possible examples. Throughout this specification, plural instances (e.g., “610”) can implement components, operations, or structures (e.g., “610a”) described as a single instance. Further, plural instances (e.g., “610”) refer collectively to a set of components, operations, or structures (e.g., “610a”) described as a single instance. The description of a single component (e.g., “610a”) applies equally to a like-numbered component (e.g., “610b”) unless indicated otherwise. These and other aspects, features, and implementations can be expressed as methods, apparatuses, systems, components, program products, means or steps for performing a function, and in other ways. These and other aspects, features, and implementations will become apparent from the following descriptions, including the examples.

The embodiments disclosed herein describe methods, apparatuses, and systems for implementing a smart device monitoring and control architecture for smart buildings. In some embodiments, a computer-implemented method for implementing an architecture for a smart building includes receiving, by one or more processors of a hub of the smart building, speech input from a smart speaker. The speech input describes multiple asynchronous events associated with multiple smart devices in the smart building. The hub is connected to a cloud Web Application Messaging Protocol (WAMP) router located in a cloud. The one or more processors convert the multiple asynchronous events to at least one of a trigger, a condition, or an action to be performed by at least one smart device of the multiple smart devices.

The one or more processors generate an automated flow for controlling at least one adapter in the smart building from at least one of the trigger, the condition, or the action. The at least one adapter operates the at least one smart device, and the at least one smart device corresponds to at least one node in the automated flow. The one or more processors determine that a third-party device is installed in the smart building. Responsive to determining that the third-party device is installed, the one or more processors generate a new adapter for the third-party device. A new node corresponding to the third-party device is generated in the automated flow. The one or more processors operate the at least one smart device and the third-party device using at least one microservice to issue remote procedure calls (RPCs) from the hub via the at least one adapter and the new adapter to the at least one smart device and the third-party device over a hub WAMP router in accordance with the automated flow by referencing the new node and the at least one node, while obviating communication between the hub and the cloud.

In some embodiments, the one or more processors prevent a first adapter operating a first smart device from communicating with a second adapter operating a second smart device of the smart building.

In some embodiments, the automated flow is generated using a visual programming language. The method includes generating, by the one or more processors, a graphical representation of the automated flow for display to a user on a graphical user interface (GUI) of the smart building, wherein the GUI is displayed on an electronic screen of the hub.

In some embodiments, the one or more processors receive text or graphical input from a user input device communicably coupled to the hub, wherein the text or graphical input references the first smart device. The one or more processors modify a portion of the automated flow corresponding to the first smart device.

In some embodiments, operating the at least one smart device and the third-party device obviates use of an Internet connection to the Hub.

In some embodiments, the at least one microservice uses publish/subscribe (pub/sub) messaging from the hub via the at least one adapter and the new adapter to the at least one smart device and the third-party device, while obviating communication between the hub and the cloud.

In some embodiments, the one or more processors add the at least one adapter, the at least one smart device, and the at least one microservice to a registry database. The one or more processors generate create, read, update and delete (CRUD) operations of the registry database via the RPCs.

In some embodiments, the one or more processors cause the at least one adapter to coordinate between a first application programming interface (API) of the hub and a second API of the at least one smart device, while obviating communication between the hub and the cloud.

In some embodiments, the adapter interfaces with the hub using WAMP, the adapter gets or sets a device state of the at least one smart device, and the adapter interfaces with the at least one smart device using at least one of hypertext transfer protocol (HTTP), MQ Telemetry Transport (MQTT), or a local daemon, while obviating communication between the hub and the cloud.

In some embodiments, the at least one microservice executes on the hub, the at least one microservice is precluded from executing on a software Snap™ package, and the adapter executes on the cloud or on a computer device of a user.

In some embodiments, the one or more processors cause the at least one microservice to establish a WebSocket connection to the cloud WAMP router.

In some embodiments, the one or more processors receive text or graphical input from a user input device, wherein the text or graphical input references the first smart device. The one or more processors send a new RPC based on the text or graphical input from the at least one microservice to the cloud WAMP router over the WebSocket connection. The one or more processors cause the cloud WAMP router to route the new RPC into the hub.

In some embodiments, the one or more processors access cloud data stored in the cloud using the hub, and preclude the cloud from accessing hub data stored in the hub.

In some embodiments, the one or more processors generate a private cryptographic key and a public cryptographic key for encrypting communication between the hub, the multiple smart devices, and the cloud WAMP router. The one or more processors store the public cryptographic key in the cloud.

In some embodiments, the one or more processors detect that the hub has lost a connection to the cloud WAMP router. The one or more processors use a public key stored on a user device of a user for encrypting communication between the hub and the multiple smart devices, wherein the public key is a copy of the public cryptographic key.

In some embodiments, the hub communicates with the at least one smart device and the third-party device using short-range wireless communication, and the short-range wireless communication is at least one of near field communication (NFC), Zigbee, Bluetooth, Wi-Fi, radio frequency identification (RFID), Z-wave, infrared (IR) wireless, 3.84 MHz wireless, EMV chips, or minimum-shift keying (MSK).

In some embodiments, the multiple smart devices comprise at least one of a water sprinkler, a door alarm, a security camera, a music player, or the smart speaker.

In some embodiments, the one or more processors extract feature vectors from training images depicting persons, animals, or objects associated with the smart building. The one or more processors train a machine learning model, based on the feature vectors, to detect new persons, new animals, or new objects that the training images are free of.

In some embodiments, the at least one smart device is a security camera. The one or more processors extract features from a video captured by the security camera. The one or more processors generate a notification using the machine learning model to a user device of a user based on the features. The notification indicates that a new person, a new animal, or a new object has been detected in the video.

In some embodiments, the at least one smart device is connected to the hub using Long Range (LoRa) communication.

In some embodiments, the one or more processors cause a user input device to receive text or graphical input via a user interface (UI) widget on the user input device, wherein the text or graphical input references the at least one smart device. The one or more processors cause the user input device to send a new RPC based on the text or graphical input from the user input device to the hub over the hub WAMP router for the hub to execute the RPC, while precluding the RPC executing on the user input device.

In some embodiments, the at least one smart device comprises a 60 gigahertz (GHz) radar sensor. The one or more processors detect motion of people, animals, or objects within rooms of the smart building over a number of days using the 60 GHz radar sensor. The one or more processors generate patterns of the motion of people, animals, or objects based on detecting the motion.

In some embodiments, the one or more processors generate feature vectors from the patterns of the motion. The one or more processors train a machine learning model, based on the feature vectors, to detect movement of the people, the animals, or the objects within rooms of the smart building, wherein the movement mismatches the patterns of the motion.

In some embodiments, the one or more processors extract features from data captured by the 60 GHz radar sensor. The one or more processors send a notification using the machine learning model to a user device of a user based on the features, the notification indicating a mismatch detected in the features.

In some embodiments, the hub, the multiple smart devices, and the at least one adapter communicate using a 900 megahertz (MHz) wireless mesh network.

In some embodiments, the hub corresponds to a realm, and another hub corresponds to another realm. The one or more processors preclude the other hub from accessing the hub or the realm. The one or more processors enable the hub and the other hub to access a service realm corresponding to the cloud.

The advantages and benefits of the methods, systems, and apparatuses disclosed herein include the prevention of services running on the cloud or a third-party device from connecting to the hub in the smart building. Therefore, no ports in the smart building's router are opened to the external Internet, and ports are prevented from exposure to external attack by malicious entities. Moreover, implementation of a static internet protocol (IP) address for the smart building is obviated. Several mechanisms are implemented by the WAMP routers and protocols to isolate components and avoid man-in-the-middle attacks. Default implementations ensure that trying to register an already-registered procedure will fail.

Combining the Publish/Subscribe (pub/sub) and routed Remote Procedure Calls in a Web-native, real-time transport protocol (WebSocket) allows WAMP to be used for messaging requirements of component- and microservice-based applications, reducing technology stack complexity and overhead, providing a capable and secure fundament for applications to rely on, Because flow-based programming (FBP) processes can continue executing as long they have data to work on and space for their output, FBP applications can run in less elapsed time than conventional programs, and make optimal use of all the processors on a machine, with no special programming required to achieve this. In addition, the advantages of the convolutional neural network (CNN) used for machine learning (ML) in the disclosed embodiments include the obviation of feature extraction and the use of shared weight in convolutional layers, which means that the same filter (weights bank) is used for each node in the layer; the weights bank both reduces memory footprint and improves performance.

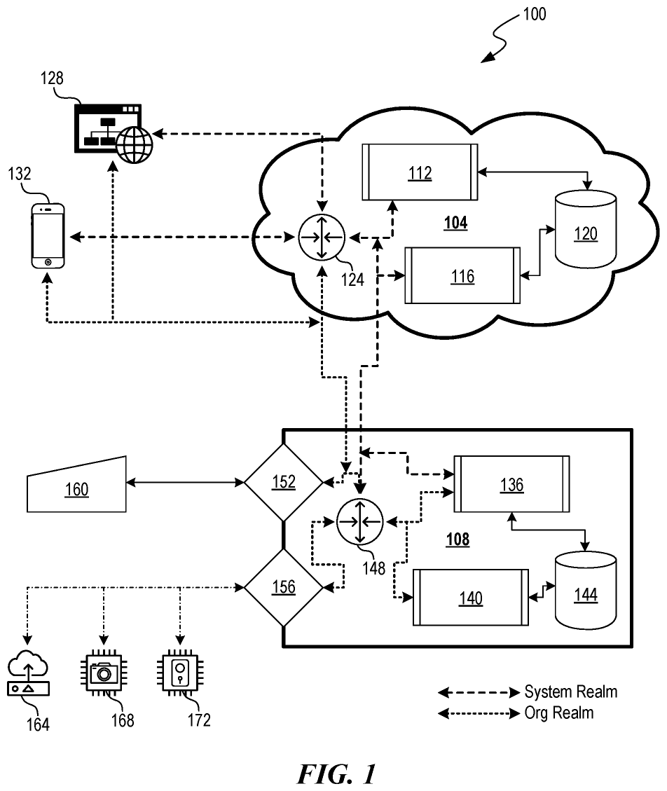

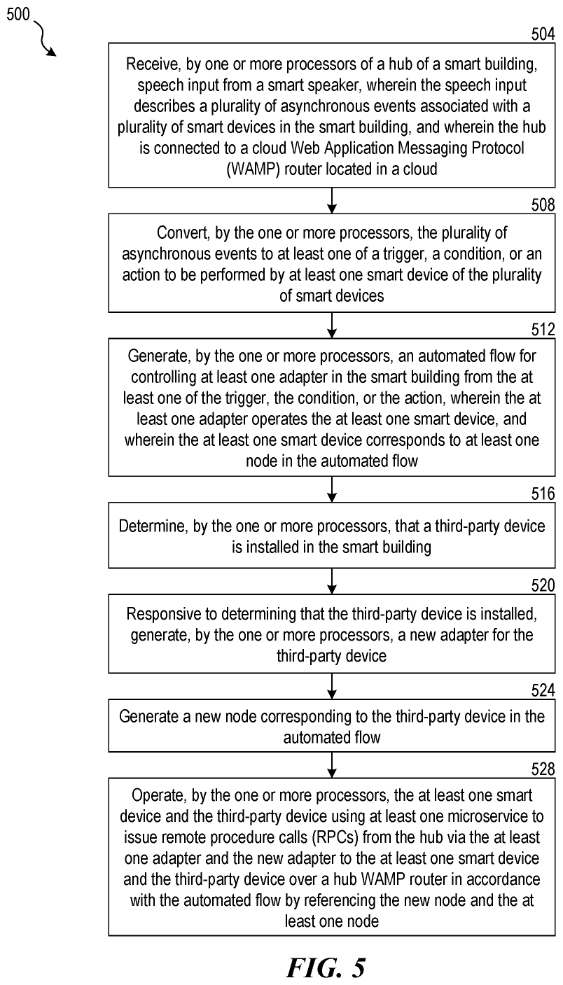

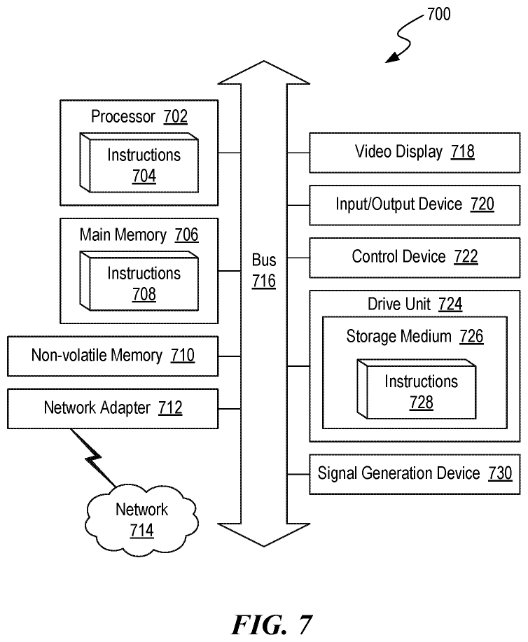

FIG. 1 is a block diagram illustrating an example smart device monitoring and control architecture 100 for smart buildings, in accordance with one or more embodiments. A smart building can be a home, office, vehicle, or vessel that uses network-connected devices to enable remote monitoring and management of appliances and systems, such as lighting and heating. The architecture 100 includes a hub 108, smart devices 164, 168, 172, and a cloud computing system 104. The smart device 164 is a smart sensor, the smart device 168 is a smart camera, and the device 172 is a smart lock (e.g., for a door, window, safe, or cabinet). The smart devices 164, 168, 172 are described in more detail with reference to FIG. 5. In some embodiments, architecture 100 includes other smart devices such as a water sprinkler, a door alarm, a security camera, a music player, or a smart speaker. The architecture 100 is implemented using the components of the example computer system 700 illustrated and described in more detail with reference to FIG. 7. Likewise, embodiments of the architecture 100 can include different and/or additional components or can be connected in different ways.

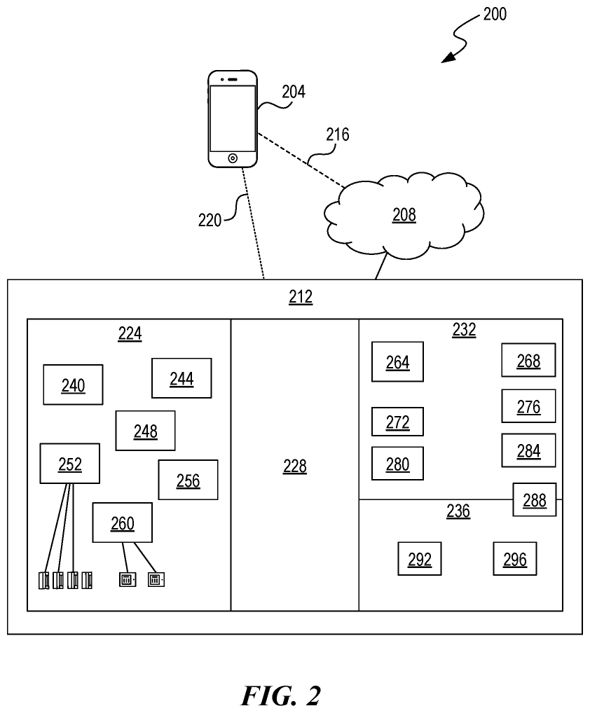

The cloud computing system 104 provides the delivery of computing services—including servers, storage, databases, networking, software, analytics, and intelligence—over the Internet to offer faster innovation, flexible resources, and economies of scale. The cloud computing system 104 includes a Web Application Messaging Protocol (WAMP) router 124 and is in communication with an account service 112 and a device registry 116, each of which has access to an open-source object-relational database 120 (e.g., a PostgreSQL open-source object-relational database). The cloud computing system 104 communicates with mobile apps 132 and web applications (web apps 128) operating on user devices. The router 124 is a WAMP router that facilitates communication between the web apps 128, mobile apps 132 on a user device, the account service 112, the device registry 116, the cloud computing system 104, and the hub 108. An example user device 204 is illustrated and described in more detail with reference to FIG. 2. WAMP routers are described in more detail with reference to FIG. 5.

The hub 108 includes a WAMP router 148 in communication with core services, also referred to as microservices 136, and an alarm service 140, each of which has access to a local SQLite database 144. Example microservices and an example alarm service (microservices 232, microservice 280) are described in more detail with reference to FIG. 2. The hub 108 communicates with zone inputs 160 via a USB port 152 and communicates with sensor(s) 164, camera 168, and door lock(s) 172 via a wireless protocol connection 156, e.g., a Long Range (LoRa) networking protocol connection or a Zigbee networking protocol connection. In some embodiments, at least one of the hub 108 or smart devices 164, 168, 172 receives electrical power and network connectivity via a universal serial bus (USB) type C port.

A smart device (e.g., sensor(s) 164, camera 168, or door lock 172) can be connected to hub 108 using LoRa communication. LoRa is a physical proprietary radio communication technique based on spread spectrum modulation techniques derived from chirp spread spectrum (CSS) technology. LoRa-WAN defines a communication protocol and system architecture. Together, LoRa and LoRa-WAN define a Low Power, Wide Area (LPWA) networking protocol designed to wirelessly connect battery operated devices to the Internet in regional, national or global networks, and targets key Internet of things (IoT) requirements such as bi-directional communication, end-to-end security, mobility and localization services. The low power, low bit rate, and IoT use distinguish this type of network from a wireless WAN that is designed to connect users or businesses, and carry more data, using more power. The LoRa-WAN data rate ranges from 0.3 kbit/s to 50 kbit/s per channel.

Any other smart home gadgets and devices are operated similarly using the embodiments disclosed herein, e.g., smart speakers, entertainment systems, surveillance systems, sprinkler systems for a garden, smart refrigerators and other smart home appliances, smart mirrors, smart locks, smart lighting, smart entry systems, climate control systems, smart detectors, smart sensors, or smart Internet routers. The WAMP router 148 facilitates communication between the microservices 136, the alarm service 140, the USB port 152, the wireless protocol connection 156, the cloud computing system 104, and the hub 108. In an embodiment, when there is no Internet service, the microservices 136 can still run or execute inside the premises because of WAMP router 148 on hub 108.

The WAMP pub/sub OTA messaging updates the UI of the mobile app 132 over a wireless network. The WAMP pub/sub OTA messaging can be used for different embedded systems including mobile phones, tablets, or set-top boxes. In some embodiments, firmware updates can be delivered OTA. In some embodiments, a device's operating system, applications, configuration settings, or parameters such as encryption keys can be updated. OTA updates are usually performed over Wi-Fi or a cellular network, but can also be performed over other wireless protocols, or over the local area network.

In some embodiments, the WebSocket protocol is used to deliver bi-directional (soft) real-time and wire traffic connections to mobile app 132. WAMP provides application developers with a level of semantics to address messaging and communication between components in distributed applications. WAMP provides PubSub functionality as well as routed Remote Procedure Calls (rRPCs) for procedures implemented in WAMP router 148. RPCs are described in more detail with reference to FIG. 5. Publish/Subscribe (PubSub) is a messaging pattern where a component, the Subscriber, informs WAMP router 148 that it wishes to subscribe to a topic. Another component, a Publisher, publishes to this topic, and the router distributes events to all Subscribers.

In some embodiments, text or graphical input is received from a user input device. The user input device can be user device 204 (see FIG. 2), another user input device such as mounted on a wall of a building or embedded in furniture, or part of another device such as a music system. The text or graphical input references a smart device (e.g., smart lock 172). A new RPC based on the text or graphical input is sent from a microservice to the cloud WAMP router 124 over the WebSocket connection. The cloud WAMP router 124 is caused to route the new RPC into hub 108. For example, the microservice is caused to establish a WebSocket connection to the cloud WAMP router 124. The microservice can execute on hub 108. In some embodiments, the microservice is precluded from executing on a software Snap™ package. An adapter (e.g., adapter 224 of FIG. 2) executes on the cloud (e.g., cloud computing system 104) or on a computer device (e.g., user device 204 of FIG. 2) of a user. A portion of an automated flow corresponding to the smart device (e.g., smart lock 172) can be modified. The automated flow is generated using flow-based programming (FBP) as described herein.

In some embodiments, hub 108 determines that smart lock 172 is a third-party device or legacy door lock. Responsive to determining that a third-party device is installed, a user interface (UI) of mobile application 132 of a user device of a user is reconfigured using WAMP pub/sub messaging delivered over-the-air (OTA) to incorporate a UI widget corresponding to smart lock 172. An example user device 204 is illustrated and described in more detail with reference to FIG. 2. A user input device can also receive text or graphical input via a UI widget on the user input device. The user input device can be user device 204 or another user input device. The UI widget (also known as a graphical control element or a control) in a graphical user interface (GUI) is an element of interaction, such as a button or a scroll bar. Controls are software components that a computer user interacts with through direct manipulation to read or edit information about an application.

In some embodiments, the text or graphical input references a smart device (e.g., smart lock 172). The user input device is caused to send a new RPC based on the text or graphical input from the user input device to hub 108 over the hub WAMP router 148 for hub 108 to execute the RPC, while precluding the RPC executing on the user input device. For example, cloud data stored in the cloud (e.g., using the cloud computing system 104 illustrated and described in more detail with reference to FIG. 1) is accessed using hub 108 while the cloud is precluded from accessing hub data stored in hub 108.

In some embodiments, an operating system (OS) of hub 108 is updated using an incremental code update delivered OTA in a software Snap™ package. The OS manages software and hardware of the hub 108 and performs basic tasks such as file, memory and process management, handling input and output, and controlling peripheral devices (e.g., smart devices 164, 168, 172). Snap™ is a software packaging and deployment system for operating systems that use the Linux kernel and the systemd init system. The packages, called snaps, and the tool for using them, snapd, work across a range of Linux™ distributions and allow upstream software developers to distribute their applications directly to users. Snaps are self-contained applications running in a sandbox with mediated access to the host system. Snap™ is operable for cloud applications, Internet of Things devices, and desktop applications.

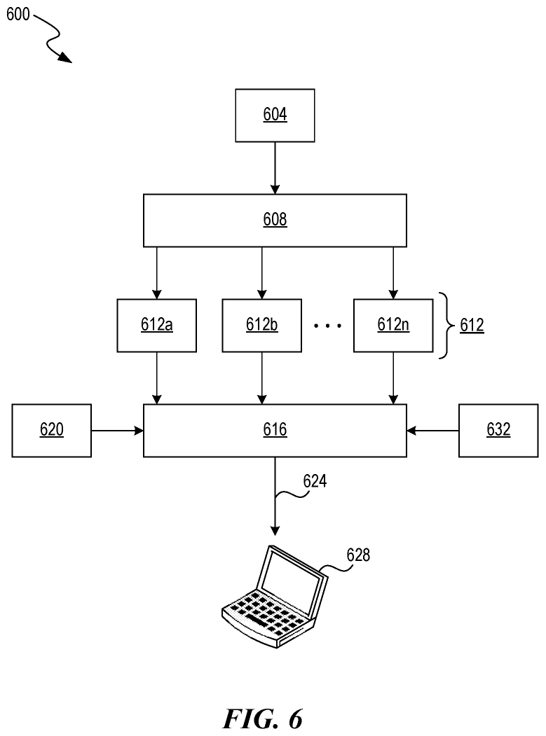

In some embodiments, a smart device (e.g., smart device 168) includes a 60 gigahertz (GHz) radar sensor. The radar sensor includes an antenna that emits a high-frequency (60 GHz) transmitted signal, which can include a modulated signal with a lower frequency (10 MHz). The sensor can be used to detect motion of people, animals, or objects within rooms of a smart building over a number of days using the 60 GHz radar sensor. Patterns of the motion of people, animals, or objects are generated based on detecting the motion. In some embodiments, feature vectors are extracted from the patterns of the motion. An example feature vector 612 and example input data 604 is illustrated and described in more detail with reference to FIG. 6. A machine learning model is trained, based on the feature vectors, to detect movement of the people, the animals, or the objects within rooms of the smart building especially when the movement mismatches the predicted patterns of the motion. An example machine learning model 616 is illustrated and described in more detail with reference to FIG. 6. In some embodiments, features are extracted from data captured by the 60 GHz radar sensor. A notification is sent using the machine learning model to user device 204 based on the features. The notification indicates a mismatch detected in the features.

In some embodiments, feature vectors are extracted from training images depicting persons, animals, or objects associated with the smart building. Feature extraction is performed as described in more detail with reference to FIG. 6. A machine learning model is trained, based on the feature vectors, to detect new persons, new animals, or new objects that the training images are free of. A smart device can be a security camera (e.g., smart camera 168 illustrated and described in more detail with reference to FIGS. 1 and 5). Features are extracted from a video captured by the security camera. A notification is generated using the machine learning model to user device 204 based on the features. The notification indicates that a new person, a new animal, or a new object has been detected in the video.

In some embodiments, operating a smart device (e.g., smart camera 168) and a third-party device (e.g., smart door lock 172) obviates the need for an Internet connection to the hub 108. Hub 108 can communicate with the smart device and the third-party device using short-range wireless communication. The short-range wireless communication can be near field communication (NFC), Zigbee, Bluetooth, Wi-Fi, radio frequency identification (RFID), Z-wave, infrared (IR) wireless, 3.84 MHz wireless, EMV chips, or minimum-shift keying (MSK). NFC is a set of communication protocols for communication between two electronic devices over a distance of 4 cm or less. NFC devices can act as electronic identity documents or keycards. NFC is based on inductive coupling between two antennas present on NFC-enabled devices—for example a smartphone and an NFC card-communicating in one or both directions, using a frequency of 13.56 MHz in the globally available unlicensed radio frequency ISM band using the ISO/IEC 18000-3 air interface standard at data rates ranging from 106 to 424 kbit/s. An NFC-enable devices, such as a smartphone (NFT creator device) can act like an NFC card, allowing users to perform transactions such as payment or ticketing.

Zigbee is a wireless technology developed as an open global standard to address the unique needs of low-cost, low-power wireless IoT networks. The Zigbee standard operates on the IEEE 802.15.4 physical radio specification and operates in unlicensed bands including 2.4 GHz, 900 megahertz (MHz) and 868 MHz. Bluetooth technology is a high-speed low powered wireless technology link that is designed to connect phones or other portable equipment together. The Bluetooth specification (IEEE 802.15.1) is for the use of low-power radio communications to link phones, computers, and other network devices over short distances without wires. Wireless signals transmitted with Bluetooth cover short distances, typically up to 30 feet (10 meters). It is achieved by embedded low-cost transceivers into the devices. Wi-Fi is a family of wireless network protocols, based on the IEEE 802.11 family of standards, which are commonly used for local area networking of devices and Internet access, allowing nearby digital devices to exchange data by radio waves.

RFID uses electromagnetic fields to automatically identify and track tags attached to objects. An RFID system consists of a tiny radio transponder, a radio receiver and transmitter. When triggered by an electromagnetic interrogation pulse from a nearby RFID reader device, the tag transmits digital data back to the reader. Passive tags are powered by energy from the RFID reader's interrogating radio waves. Active tags are powered by a battery and thus can be read at a greater range from the RFID reader, up to hundreds of meters.

Z-Wave is a wireless communications protocol on a mesh network using low-energy radio waves to communicate from appliance to appliance, allowing for wireless control of devices. A Z-Wave system can be controlled via the Internet from a smart phone, tablet, or computer, and locally through a smart speaker, wireless key fob, or wall-mounted panel. IR wireless is the use of wireless technology in devices or systems that convey data through infrared (IR) radiation. Infrared is electromagnetic energy at a wavelength or wavelengths somewhat longer than those of red light. The shortest-wavelength IR borders visible red in the electromagnetic radiation spectrum; the longest-wavelength IR borders radio waves.

FIG. 2 is a drawing illustrating an example hub 212 in an architecture 200 for smart buildings, in accordance with one or more embodiments. The architecture 200 is similar to or same as the architecture 100 illustrated and described in more detail with reference to FIG. 1. The architecture 200 includes a user device 204, a cloud computing system 208, and the hub 212. The architecture 200 is implemented using the components of the example computer system 700 illustrated and described in more detail with reference to FIG. 7. Likewise, embodiments of the architecture 200 can include different and/or additional components or can be connected in different ways.

The user device 204 is a smartphone, other mobile device, tablet, smartwatch, desktop, or laptop. The user device 204 has a connection 220 to the hub 212 via a local area network (LAN) or other short-range wired or wireless connection. The user device 204 has a fallback connection 216 to the cloud computing system 208. In some embodiments, the hub 212, multiple smart devices in the smart building, and an adapter communicate using a 900 MHz wireless mesh network. The wireless mesh network is a communications network made up of radio nodes organized in a mesh topology. It can also be a form of wireless ad hoc network. For example, the mesh network uses LoRa communication.

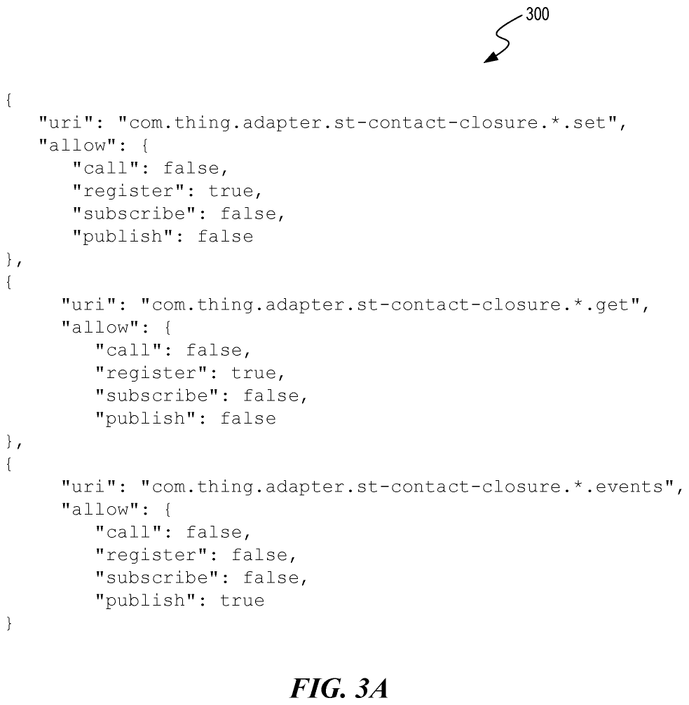

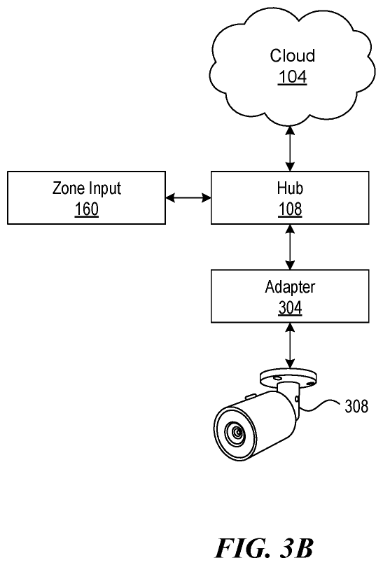

The hub 212 includes adapters 224, a WAMP router 228, applications and microservices 232, and flow services 236. Adapters are described in more detail with reference to FIGS. 3A, 3B, and 5. The hub 212 communicates with a WAMP router 124 in the cloud computing system 208 using the WAMP router 228. WAMP and WAMP routers are described in more detail with reference to FIG. 5. The router 124 is illustrated and described in more detail with reference to FIG. 1.

In some embodiments, hub 212, the multiple smart devices (e.g., smart camera 168 illustrated and described in more detail with reference to FIGS. 1 and 5), and adapter 224 each include a respective encryption module to encrypt the LoRa communication using a private cryptographic key stored in the hub 212 and a public cryptographic key stored in the cloud (e.g., using the cloud computing system 104 illustrated and described in more detail with reference to FIG. 1). An encryption module is a physical computing device that safeguards and manages secrets (most importantly digital keys), performs encryption and decryption functions for digital signatures, strong authentication and other cryptographic functions. The encryption module can be a plug-in card or an external device, and can contain one or more secure crypto-processor chips. The private cryptographic key (also known as a secret key) is a variable in cryptography that is used with an algorithm to encrypt and decrypt data, e.g., using symmetric cryptography or asymmetric cryptography.

The public cryptographic key can be a large numerical value used to encrypt data. The public cryptographic key can be generated by a software program or provided by a trusted, designated authority and made available via a publicly accessible repository or directory. In some embodiments, a private cryptographic key and a public cryptographic key are generated for encrypting communications between hub 212, multiple smart devices, and the cloud WAMP router 124. The public cryptographic key is stored in the cloud (e.g., using the cloud computing system 104 illustrated and described in more detail with reference to FIG. 1).

In some embodiments, a computer system implemented at the hub 212 detects that the hub 212 has lost external electrical power from the mains. The hub 212, the smart devices, third-party devices, and/or the wireless mesh network are powered using a 12 V uninterruptible power supply (UPS). For example, the UPS is embedded in a wall or floor of the smart building. A UPS or uninterruptible power source is an electrical apparatus that provides emergency power to a load when the input power source or mains power fails. A UPS provides near-instantaneous protection from input power interruptions, by supplying energy stored in batteries, supercapacitors, or flywheels. The on-battery run-time is relatively short (only a few minutes) but sufficient to start a standby power source or properly shut down the protected equipment.

In some embodiments, hub 212 determines that hub 212 has lost an Internet connection. Hub 212 causes a UI of a mobile application to send RPCs to hub 212 over the 900 MHz wireless mesh network of the smart building. Example mobile apps 132 are illustrated and described in more detail with reference to FIG. 1. RPCs are described in more detail with reference to FIG. 5. Hub 212 is connected to the cloud using an LTE or 5G connection of the user device 204. In some embodiments, the one or more processors detect that hub 212 has lost a connection to the cloud WAMP router 124. In response, a public key stored on user device 204 is used for encrypting communication between hub 212 and multiple smart devices (e.g., the smart lock 172 illustrated and described in more detail with reference to FIG. 1). The public key is a copy of a public cryptographic key used by the system according to the embodiments disclosed herein.

The adapter 240 is a Zigbee adapter. The adapter 240 enables Zigbee wireless connectivity with an RP-C controller, AS-P server, or AS-B server, extending the controller's or server's point count and bringing flexibility in retrofit applications. The adapter 244 is an input module adapter. The adapter 244 operates input modules that detect the status of input signals such as push-buttons, smart switches, or smart temperature sensors. The adapter 248 operates output modules such as hub relays. An output module controls devices such as relays, motor starters, or smart lights. The adapter 252 is a contact closure adapter. The adapter 252 operates contact closures designed for connecting smart switches, buttons, smart motion detectors, or other devices that make an electrical connection between two conductors. The adapter 252 operates digital outputs designed for connecting smart LED indicators, small relays, buzzers, pilot lights, and other devices powered from a small DC voltage.

The adapter 256 is a notification adapter. For example, the adapter 256 sends push notifications or clickable pop-up messages that appear on a user's browser irrespective of the device they're using or the browser they're on. The notifications serve as a quick communication channel enabling smart devices or the hub 212 to convey messages. In some embodiments, the adapter 256 sends Short Message Service (SMS) notifications or Multimedia Messaging Service (MMS) notifications to the user device 204. The notifications can include multimedia content such as videos, pictures, GIFs, and audio files. The adapter 260 is a keypad adapter and operates one or more keypads. The keypad can control a smart device such as the smart lock 172 illustrated and described in more detail with reference to FIG. 1 or send messages to the hub 212.

The applications and microservices 232 include a resource manager microservice 264. The microservice 264 serves as a registry (database) for adapters, services, groups, and devices. The microservice 264 exposes database create, read, update and delete (CRUD) operations via WAMP RPCs. An adapter or service manifest requests permissions that are approved by a user. Upon approval, the microservice 264 generates a dynamic authorization. A default permission exists to allow an adapter or service to publish within its own namespace. The microservice 284 is an activity service. A uniform resource identifier (URI) includes adapter identifiers (IDs) and/or Universally Unique Identifiers (UUIDs) for granular control of smart devices. In some embodiments, the UUIDS are 128-bit numbers, composed of 16 octets and represented as 32 base-16 characters, that can be used to identify information across a computer system. For example, the microservice 284 or a Mobile App on the user device 204 can access one or more events when given appropriate permissions. In some embodiments, an adapter, a smart device, and a microservice are added to a registry database. CRUD operations of the registry database are generated via RPCs.

The microservice 268 is a provisioning service. The microservice 268 on-boards the hub 212 into a user's account. The microservice 268 allows the user to configure Wi-Fi settings over Bluetooth. The microservice 276 is a Groups Service. The microservice 276 allows groups to be used in automated flows. FBP is a programming paradigm that defines applications as networks of “black box” processes, which exchange data across predefined connections by message passing, where the connections are specified externally to the processes. These black box processes can be reconnected endlessly to form different applications without having to be changed internally. FBP is thus naturally component-oriented.

An automated flow can be generated in the cloud (e.g., using the cloud computing system 104 illustrated and described in more detail with reference to FIG. 1) using by user device 204. Operating a smart device (e.g., smart camera 168 illustrated and described in more detail with reference to FIGS. 1 and 5) in accordance with the automated flow is performed in hub 212. FBP is a particular form of dataflow programming based on bounded buffers, information packets with defined lifetimes, named ports, and separate definition of connections. FBP defines applications using the metaphor of a “data factory.” It views an application as a network of asynchronous processes communicating by means of streams of structured data chunks, called “information packets.” In this view, the focus is on the application data and the transformations applied to it to produce the desired outputs. The network is defined externally to the processes, as a list of connections which is interpreted by a piece of software, usually called the “scheduler.” The processes communicate by means of fixed-capacity connections.

A connection is attached to a process by means of a port, which has a name agreed upon between the process code and the network definition. More than one process can execute the same piece of code. At any point in time, a given IP can only be “owned” by a single process, or be in transit between two processes. Ports may either be simple, or array-type, as used e.g. for the input port of a Collate component. It is the combination of ports with asynchronous processes that allows many long-running primitive functions of data processing, such as Sort, Merge, or Summarize to be supported in the form of software black boxes. In some embodiments, text or graphical input is received from a user input device communicably coupled to hub 212. The text or graphical input references a smart device (e.g., smart camera 168 illustrated and described in more detail with reference to FIGS. 1 and 5). A portion of the automated flow corresponding to the smart device is modified.

The microservice 276 subscribes to events for a device in a group and re-publishes those device events on the group topic. The microservice 276 also allows a user to set (e.g., using a SET command) the state of all devices in a group that have a common capability set. The microservice 272 is a watchdog or bootstrap microservice. The microservice 272 runs on the hub 212 directly (not in a Snap) and provides one or more of the following capabilities: (1) RPC to get a list of services/adapters (available Snaps from an external repo, e.g., “Snap store”), (2) RPC to install a service/adapter, (3) RPC to remove a service/adapter, (4) RPC to get a list of running services/adapters, (5) RPC to stop or start a service/adapter, and (5) RPC to control startup of a service/adapter (on hub boot), i.e., a startup priority/dependency tree, e.g., start resource manager first, wait for health check, then start adapters. The microservice 280 is an alarm service that provides functionality for alarms. The microservice 280 receives messages from one or more Alarm Gateways, and manages the current alarm states in the context of the equipment model, including the alarm lists associated with each smart device, e.g., smart lock 172.

The flow services 236 include a date and time service 292 and a weather service 296. A flow service 288 is a codebase that provides non-core functions to automated flows. The hub 212 has microservices pre-installed for push notifications, weather, and more. A microservice also includes a manifest that includes triggers, conditions, and actions. The triggers, conditions, and actions are explicitly defined by a schema as a set of setters and getters.

FIG. 3A is a drawing illustrating code for an example adapter for smart buildings, in accordance with one or more embodiments. The adapter operates a smart device, e.g., the smart sensor 164 illustrated and described in more detail with reference to FIG. 1. For example, one or more processors generate an automated flow for controlling the adapter from at least one of a trigger, a condition, or an action. The smart device corresponds to a node in the automated flow. The adapter provides a programming interface to control and manage specific lower level interfaces linked to the smart device.

In some embodiments, the adapter communicates with the smart device through the communications subsystem (see FIG. 1) to which the smart device connects. When a calling program invokes a routine in the adapter, the adapter issues commands to the smart device. Once the smart device sends data back to the adapter, the adapter invokes routines in the original calling program. The adapter provides the interrupt handling required for asynchronous time-dependent device behavior. An example adapter 304 is illustrated and described in more detail with reference to FIG. 3B. In some embodiments, the automated flow is exported as a JavaScript Object Notation (JSON) for operating a smart device in accordance with the automated flow. JSON is an open standard file format and data interchange format that uses human-readable text to store and transmit data objects consisting of attribute—value pairs and arrays. JSON has diverse uses in electronic data interchange, including that of web applications with servers.

In some embodiments, one or more processors (e.g., in the hub 108 of FIG. 1) cause the adapter to coordinate between a first application programming interface (API) of the hub 108 and a second API of the smart device, while obviating communication between the hub 108 and the cloud computing system 104 (see FIG. 1). The hub 108 and cloud computing system 104 are illustrated and described in more detail with reference to FIG. 1. The embodiments thus enable the data to be held privately and not transferred to the cloud computing system 104. In some embodiments, the adapter interfaces with the hub 108 using WAMP. WAMP is described in more detail with reference to FIG. 5. The adapter gets or sets a device state (e.g., ON, OFF, RESET, SLEEP, or LISTENING) of the smart device. The adapter interfaces with the smart device using at least one of hypertext transfer protocol (HTTP), MQ Telemetry Transport (MQTT), or a local daemon, while obviating communication between the hub 108 and the cloud computing system 104. The embodiments thus provide information privacy (for collection and dissemination of data) in accordance with a public expectation of privacy. Data privacy and data protection is enabled by using data by the hub 108 while protecting an individual's privacy preferences and personally identifiable information.

FIG. 3B is a block diagram illustrating example connectivity for an architecture 100 for smart buildings, in accordance with one or more embodiments. The architecture 100 is illustrated and described in more detail with reference to FIG. 1. The example connectivity includes connections between the cloud computing system 104, hub 108, adapter 304, zone input 160 and smart device 308. Operations of an adapter are illustrated and described in more detail with reference to FIGS. 3A and 5. The cloud computing system 104, hub 108, and zone input 160 are illustrated and described in more detail with reference to FIG. 1. The example connectivity is implemented using the components of the example computer system 700 illustrated and described in more detail with reference to FIG. 7. Likewise, embodiments of the example connectivity can include different and/or additional components or can be connected in different ways. For example, the adapter 304 can be implemented on the hub 108 or the smart device 308. The smart device 308 is similar to or the same as the smart camera 168 illustrated and described in more detail with reference to FIGS. 1 and 5.

The adapter 304 is a codebase that translates interfaces between APIs and individual device or device ecosystem APIs. Adapters have a “northbound” or “southbound” interface of WAMP and implement specific functions, such as “get device state” and “set device state.” The other interface of each adapter (i.e., “southbound” or “northbound,” respectively) will vary by adapter, e.g., MQTT, HTTP, or local daemon. A northbound interface of an adapter is an interface that allows the adapter to communicate with a higher level component, using the latter component's southbound interface. The northbound interface conceptualizes the lower level details (e.g., data or functions) used by, or in, the adapter, allowing the adapter to interface with higher level layers. The southbound interface decomposes concepts in the technical details, mostly specific to a single component of the architecture. A northbound interface is typically an output-only interface (as opposed to one that accepts user input).

The hub 108 includes adapters pre-installed for smart devices (e.g., contact closure, or keypad). Additional adapters can be installed from an “adapter store.” The adapter 304 includes a manifest (JSON) which includes properties such as adapter_id, name, input fields required for provisioning, or permissions required. The adapter 304 announces its manifest to the resource manager upon startup and the resource manager stores it in its database. An Adapter SDK is provided in several languages that will accelerate the development of adapters for internal use and the developer community. The adapter 304 is able to run in the cloud, on another device, or by a third party. The adapter 304's permissions allow it to only register RPCs and publish messages within a particular namespace.

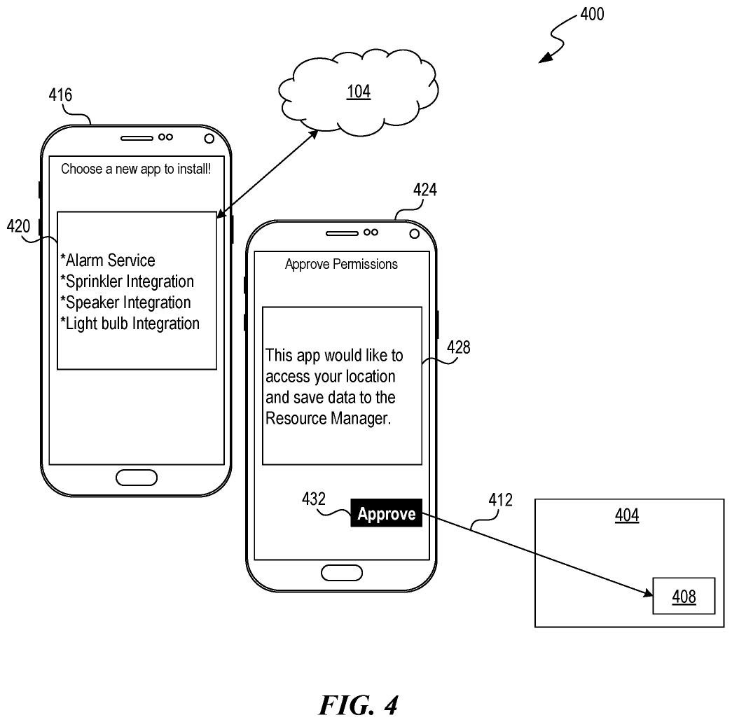

FIG. 4 is a drawing illustrating example microservices for an architecture 400 for smart buildings, in accordance with one or more embodiments. The architecture 400 is similar to or the same as the architecture 100 illustrated and described in more detail with reference to FIG. 1. The architecture 400 is implemented using the components of the example computer system 700 illustrated and described in more detail with reference to FIG. 7. Likewise, embodiments of the microservices can include different and/or additional steps or can be ordered in different ways.

The architecture 400 includes two user devices 416, 424, a cloud computing system 104, and a hub 404. The cloud computing system 104 is illustrated and described in more detail with reference to FIG. 1. The hub 404 is similar to or the same as the hub 108 illustrated and described in more detail with reference to FIG. 1. The cloud computing system 104 includes an app store. A user visits the app store using the user device 416 to see a list of new services and integrations 420 offered by the cloud computing system 104 or third parties. When the user selects an “app,” they are prompted to approve the permissions 428 that the app is requesting, using one of the two user devices 416, 424. Upon granting permissions, the app 432 asks the Watchdog microservice 408 (running on the hub 404) to install the selected app. The microservice 408 is similar to or same as the microservice 272 illustrated and described in more detail with reference to FIG. 2.

The request 412 is made over WAMP. WAMP is described in more detail with reference to FIG. 5. The request 412 is directed to the hub 404 if the user is in the smart building, otherwise the request 412 is routed through the WAMP cloud router 124 to the hub 404. The router 124 is described in more detail with reference to FIG. 1. The Watchdog microservice 408 verifies that the new app is approved and notarized, and performs the installation. The microservice 268 guides the user through the provisioning process for the new service. The microservice 268 is described in more detail with reference to FIG. 2.

FIG. 5 is a flow diagram illustrating an example process 500 for an architecture for smart buildings, in accordance with one or more embodiments. An example architecture 100 is illustrated and described in more detail with reference to FIG. 1. In some embodiments, the process of FIG. 5 is performed by the hub 108 illustrated and described in more detail with reference to FIG. 1. In some embodiments, the process of FIG. 5 is performed by a computer system, e.g., the example computer system 700 illustrated and described in more detail with reference to FIG. 7. Particular entities, for example, the core services module 136, perform some or all of the steps of the process in some embodiments. The core services module 136 is illustrated and described in more detail with reference to FIG. 1. Likewise, embodiments can include different and/or additional steps, or perform the steps in different orders.

In step 504, one or more processors of the hub 108 of the smart building 100 receive speech input from a smart speaker. The speech input describes multiple asynchronous events associated with multiple smart devices (e.g., smart devices 164, 168, 172) in the architecture 100. The smart device 164 is a smart sensor, the smart device 168 is a smart camera, and the smart device 172 is a smart lock. The hub is connected to a cloud WAMP router 124 located in a cloud computing system 104. The WAMP router 124 and cloud computing system 104 are illustrated and described in more detail with reference to FIG. 1.

A smart speaker is a type of loudspeaker and voice command device with an integrated virtual assistant that offers interactive actions and hands-free activation with the help of one “hot word” (or several “hot words”). Some smart speakers can also act as smart devices that utilize Wi-Fi, Bluetooth and other protocol standards to extend usage beyond audio playback, such as to control home automation devices. The implementations can include, but are not limited to, features such as compatibility across a number of services and platforms, peer-to-peer connection through mesh networking, virtual assistants, and others. Each can have its own designated interface and features in-house, usually launched or controlled via application or home automation software. Some smart speakers also include a screen to show the user a visual response.

WAMP is a WebSocket subprotocol specified to offer routed RPC and PubSub messaging. It provides an open standard for soft, real-time message exchange between application components and eases the creation of loosely coupled architectures based on microservices. The WAMP router 124 is used as an enterprise service bus (ESB) for developing responsive Web applications or to coordinate multiple connected smart devices in the architecture 100. WAMP uses a reliable, ordered, full-duplex message channel as a transport layer, and by default uses WebSocket. However, implementations can use other transports matching these characteristics and communicate with WAMP over, for example, raw sockets, Unix sockets, or HTTP long poll. In some embodiments, message serialization uses integers, strings, and ordered sequence types, and defaults to JSON as a common format offering these. Implementations can provide MessagePack as a faster alternative to JSON.

WAMP is architected around client—client communications. The router 124 dispatches messages between the cloud computing system 104 and the hub 108. For data exchange, client microservices connect to the hub's WAMP router 148 using a transport, establishing a session. The router 148 is illustrated and described in more detail with reference to FIG. 1. The router 148 identifies the clients and gives them permissions for the current session. Clients send messages to the router 148, which dispatches them to the proper targets using the attached URIs. The clients send these messages using the two high-level primitives that are RPC and Pub/Sub, doing four core interactions: (1) register: a client exposes a procedure to be called remotely, (2) call: a client asks the router 148 to get the result of an exposed procedure from another client, (3) subscribe: a client notifies its interest in a topic, and (4) publish: a client publishes information about the topic.

As WAMP uses WebSocket, connections can be wrapped in Transport Layer Security (TLS) for encryption. TLS is the successor protocol to Secure Sockets Layer (SSL). TLS is an improved version of SSL. It works in much the same way as the SSL, using encryption to protect the transfer of data and information. In some embodiments, hub 108 corresponds to a first realm, and a second, different hub corresponds to a second realm. A “realm” refers to a WAMP routing and administrative domain, optionally protected by authentication and authorization. WAMP messages are typically routed within a Realm.

The second hub is precluded from accessing the hub 108 or the first realm. The one or more processors enable hub 108 and the second hub to access a service realm corresponding to the cloud. For example, WAMP router 148 (see FIG. 1) can define realms as administrative domains, and clients must specify which realm they want to join upon connection. Once joined, the realm will act as a namespace, preventing clients connected to a realm from using IDs defined in another realm for RPC and PubSub. In some embodiments, a first adapter operating a first smart device 164 is prevented from communicating with a second adapter operating a second smart device 168 of the architecture 100. An example adapter 304 is illustrated and described in more detail with reference to FIG. 3B. For example, realms also have permissions attached and can limit the client microservices to one subset of the REGISTER/CALL/PubSub actions available. Some realms can only be joined by authenticated clients, using various authentication methods such as using TLS certificate, cookies or a simple ticket.

In step 508, one or more processors of the hub 108 convert the multiple asynchronous events to at least one of a trigger, a condition, or an action to be performed by one of the multiple smart devices 164, 168, 172. The smart devices 164, 168, 172 are illustrated and described in more detail with reference to FIG. 1. Smart sensor 164 produces an output signal for the purpose of sensing a physical phenomenon. The smart sensor 164 is a module, machine, or subsystem that detects events or changes in its environment and sends the information to other electronics, frequently a computer processor. The sensor 164 is used in everyday objects such as touch-sensitive elevator buttons (tactile sensor) and lamps which dim or brighten by touching the base, and in innumerable applications. With advances in micromachinery and the easy-to-use architecture 100, the uses of sensors 164 include temperature, pressure, potentiometers and force-sensing resistors, sensors that measure chemical and physical properties, optical sensors, vibrational sensors, and electro-chemical sensors.

The smart lock 172 pairs with the hub 108 for entry without a key, and to manage access to the lock 172 remotely. In some embodiments, the lock 172 is retrofitted to a traditional lock instead of replacing the existing deadbolt, or has user code limits, automatic locking, or connects with an existing security system. In some embodiments, the smart camera 168 performs continuous recording, or has a motion sensor, a rechargeable battery, or apps that send a push notification to the hub 108 when something triggers the camera 168. In some embodiments, the camera 168 has 1080p resolution or better and connects to an existing smart home setup or smart devices. A trigger refers to procedural code that is automatically executed in response to an event such as a rising edge on a signal. A condition refers to a material conditional (also known as material implication) and serves as the basis for commands in programming languages. An action refers to a step performed by the hub 108, or smart devices 164, 168.

In some embodiments, to generate an automated flow, one or more processors extract a feature vector from the speech input. An example feature vector 612 and example input data 604 is illustrated and described in more detail with reference to FIG. 6. The one or more processors generate a synchronous event using a machine learning model based on the feature vector to provide the automated flow. An example machine learning model 616 is illustrated and described in more detail with reference to FIG. 6. The machine learning model is trained to convert an asynchronous event to the synchronous event for controlling an adapter.

The adapter operates a smart device referenced by features input to the machine learning model. For example, in step 512, the one or more processors generate an automated flow for controlling an adapter in the smart building 100 from the trigger, the condition, or the action. An automated flow can be generated using a visual programming language. A graphical representation of the automated flow is generated for display to a user on a GUI of the smart building. The GUI is displayed on an electronic screen of the hub.

The adapter can operate a smart device. The smart device corresponds to a node in the automated flow. An adapter provides a programming interface to control and manage specific lower level interfaces linked to a smart device, e.g., smart sensor 164. In some embodiments, the adapter communicates with the smart sensor 164 through the communications subsystem to which the smart sensor 164 connects. When a calling program invokes a routine in the adapter, the adapter issues commands to the smart sensor 164. Once the smart sensor 164 sends data back to the adapter, the adapter invokes routines in the original calling program. An adapter provides the interrupt handling required for asynchronous time-dependent device behavior.

In step 516, the one or more processors determine that a third-party device is installed in the smart building. For example, the hub 108 determines that the smart lock 172 is a third-party or legacy door lock. The third-party device can be a legacy device or be installed by a different entity than the entity installing the hub 108. In step 520, responsive to determining that the third-party device is installed, the one or more processors generate a new adapter for the third-party device. The embodiments thus solve the problem of legacy heating units, security cameras, or entertainment units not integrating with the architecture 100 shown by FIG. 1.

In step 524, the one or more processors generate a new node corresponding to the third-party device in the automated flow. In some embodiments, the node-based flow is used to define object-oriented (00) classes or objects in an engine of the hub 108. Nodes are the primary building block of the automated flow. When the automated flow is running, messages are generated, consumed and processed by nodes. For example, nodes include code that runs in a JavaScript (.js) file, and an HTML file consisting of a description of the node, so that it appears in the node pane with a category, color, name and an icon, code to configure the node, and help text. Nodes can have an input, and zero or more outputs.

In step 528, the one or more processors operate a smart device and the third-party device using a microservice to issue remote procedure calls (RPCs) from the hub 108 via the adapter and the new adapter to the smart device and the third-party device over the hub's WAMP router 148 in accordance with the automated flow by referencing the new node and the node, while obviating communication between the hub 108 and the cloud computing system 104. For example, unlike with traditional RPCs, which are addressed directly from a caller to the entity offering the procedure (typically a server backend) and are strictly unidirectional (client-to-server), RPCs in WAMP are routed by a middleware and work bidirectionally. Registration of RPCs is with the hub's WAMP router 148, and calls to procedures are similarly issued to the hub's WAMP router 148. In some embodiments, a microservice uses pub/sub messaging from the hub via an adapter and a new adapter to a smart device and a third-party device, while obviating communication between the hub and the cloud.

A client microservice can issue RPCs via the single connection to the hub's WAMP router 148. The client microservice does not need to have knowledge of which client is currently offering a particular procedure, where that client resides, or how to address the client. The process can change between calls, opening up the possibility for advanced features such as load-balancing or fail-over for procedure calls. Additionally, the WAMP client microservices offer different procedures for calling. The different procedures avoid the traditional distinction between clients and server backends, and enable architectures where browser clients call procedures on other browser clients using an API similar to peer to peer communication.

FIG. 6 is a block diagram illustrating an example machine learning (ML) system 600, in accordance with one or more embodiments. The ML system 600 is implemented using components of the example computer system 700 illustrated and described in more detail with reference to FIG. 7. For example, the ML system 600 can be implemented using instructions 728 programmed in the storage medium 726 illustrated and described in more detail with reference to FIG. 7. Likewise, embodiments of the ML system 600 can include different and/or additional components or be connected in different ways. The ML system 600 is sometimes referred to as a ML module.

The ML system 600 includes a feature extraction module 608 implemented using components of the example computer system 700 illustrated and described in more detail with reference to FIG. 7. In some embodiments, the feature extraction module 608 extracts a feature vector 612 from input data 604. For example, the input data 604 can include patterns or videos of motion of people, animals, or objects as described in more detail with reference to FIG. 1. The feature vector 612 includes features 612a, 612b, . . . , 612n. The feature extraction module 608 reduces the redundancy in the input data 604, e.g., repetitive data values, to transform the input data 604 into the reduced set of features 612, e.g., features 612a, 612b, . . . , 612n. The feature vector 612 contains the relevant information from the input data 604, such that events or data value thresholds of interest can be identified by the ML model 616 by using the reduced feature representation. In some example embodiments, the following dimensionality reduction techniques are used by the feature extraction module 608: independent component analysis, Isomap, kernel principal component analysis (PCA), latent semantic analysis, partial least squares, PCA, multifactor dimensionality reduction, nonlinear dimensionality reduction, multilinear PCA, multilinear subspace learning, semidefinite embedding, autoencoder, and deep feature synthesis.

In alternate embodiments, the ML model 616 performs deep learning (also known as deep structured learning or hierarchical learning) directly on the input data 604 to learn data representations, as opposed to using task-specific algorithms. In deep learning, no explicit feature extraction is performed; the features 612 are implicitly extracted by the ML system 600. For example, the ML model 616 can use a cascade of multiple layers of nonlinear processing units for implicit feature extraction and transformation. Each successive layer uses the output from the previous layer as input. The ML model 616 can thus learn in supervised (e.g., classification) and/or unsupervised (e.g., pattern analysis) modes. The ML model 616 can learn multiple levels of representations that correspond to different levels of abstraction, wherein the different levels form a hierarchy of concepts. The different levels configure the ML model 616 to differentiate features of interest from background features.

In alternative example embodiments, the ML model 616, e.g., in the form of a convolutional neural network (CNN), generates the output 624, without the need for feature extraction, directly from the input data 604. The output 624 is provided to the computer device 628 or the hub 108 illustrated and described in more detail with reference to FIG. 1. The computer device 628 is a server, computer, tablet, smartphone, or smart speaker implemented using components of the example computer system 700 illustrated and described in more detail with reference to FIG. 7. In some embodiments, the steps performed by the ML system 600 are stored in memory on the computer device 628 for execution. In some embodiments, the output 624 is displayed on a screen of the hub 108 or smart devices 164, 168, 172 illustrated and described in more detail with reference to FIG. 1.

A CNN is a type of feed-forward artificial neural network in which the connectivity pattern between its neurons is inspired by the organization of a visual cortex. Individual cortical neurons respond to stimuli in a restricted area of space known as the receptive field. The receptive fields of different neurons partially overlap such that they tile the visual field. The response of an individual neuron to stimuli within its receptive field can be approximated mathematically by a convolution operation. CNNs are based on biological processes and are variations of multilayer perceptrons designed to use minimal amounts of preprocessing.

The ML model 616 can be a CNN that includes both convolutional layers and max pooling layers. The architecture of the ML model 616 can be “fully convolutional,” which means that variable sized sensor data vectors can be fed into it. For all convolutional layers, the ML model 616 can specify a kernel size, a stride of the convolution, and an amount of zero padding applied to the input of that layer. For the pooling layers, the model 616 can specify the kernel size and stride of the pooling.

In some embodiments, the ML system 600 trains the ML model 616, based on the training data 260, to correlate the feature vector 612 to expected outputs in the training data 620. As part of the training of the ML model 616, the ML system 600 forms a training set of features and training labels by identifying a positive training set of features that have been determined to have a desired property in question, and, in some embodiments, forms a negative training set of features that lack the property in question.

The ML system 600 applies ML techniques to train the ML model 616, that when applied to the feature vector 612, the ML model 616 outputs indications of whether the feature vector 612 has an associated desired property or properties, such as a probability that the feature vector 612 has a particular Boolean property, or an estimated value of a scalar property. The ML system 600 can further apply dimensionality reduction (e.g., via linear discriminant analysis (LDA), principal component analysis (PCA), or the like) to reduce the amount of data in the feature vector 612 to a smaller, more representative set of data.

The ML system 600 can use supervised ML to train the ML model 616, with feature vectors of the positive training set and the negative training set serving as the inputs. In some embodiments, different ML techniques, such as linear support vector machine (linear SVM), boosting for other algorithms (e.g., AdaBoost), logistic regression, naïve Bayes, memory-based learning, random forests, bagged trees, decision trees, boosted trees, boosted stumps, neural networks, or CNNs are used. In some example embodiments, a validation set 632 is formed of additional features, other than those in the training data 620, which have already been determined to have or to lack the property in question. The ML system 600 applies the trained ML model 616 to the features of the validation set 632 to quantify the accuracy of the ML model 616. Common metrics applied in accuracy measurement include: Precision and Recall, where Precision refers to a number of results the ML model 616 correctly predicted out of the total it predicted, and Recall is a number of results the ML model 616 correctly predicted out of the total number of features that had the desired property in question. In some embodiments, the ML system 600 iteratively re-trains the ML model 616 until the occurrence of a stopping condition, such as the accuracy measurement indication that the ML model 616 is sufficiently accurate, or a number of training rounds having taken place. The data enables the detected values to be validated using the validation set 632. The validation set 632 can be generated based on analysis to be performed.

In some embodiments, ML system 600 is a generative artificial intelligence or generative AI system capable of generating text, images, or other media in response to prompts. Generative AI systems use generative models such as large language models to produce data based on the training data set that was used to create them. A generative AI system is constructed by applying unsupervised or self-supervised machine learning to a data set. The capabilities of a generative AI system depend on the modality or type of the data set used. For example, generative AI systems trained on words or word tokens are capable of natural language processing, machine translation, and natural language generation and can be used as foundation models for other tasks. In addition to natural language text, large language models can be trained on programming language text, allowing them to generate source code for new computer programs. Generative AI systems trained on sets of images with text captions are used for text-to-image generation and neural style transfer.

FIG. 7 is a block diagram illustrating an example computer system 700, in accordance with one or more embodiments. Components of the example computer system 700 can be used to implement the hub 108 and other components illustrated and described in more detail with reference to FIG. 1. In some embodiments, components of the example computer system 700 are used to implement the ML system 600 illustrated and described in more detail with reference to FIG. 6. At least some operations described herein can be implemented on the computer system 700.

The computer system 700 can include one or more central processing units (“processors”) 702, main memory 706, non-volatile memory 710, network adapters 712 (e.g., network interface), video displays 718, input/output devices 720, control devices 722 (e.g., keyboard and pointing devices), drive units 724 including a storage medium 726, and a signal generation device 720 that are communicatively connected to a bus 716. The bus 716 is illustrated as an abstraction that represents one or more physical buses and/or point-to-point connections that are connected by appropriate bridges, adapters, or controllers. The bus 716, therefore, can include a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 1394 bus (also referred to as “Firewire”).

The computer system 700 can share a similar computer processor architecture as that of a desktop computer, tablet computer, personal digital assistant (PDA), mobile phone, game console, music player, wearable electronic device (e.g., a watch or fitness tracker), network-connected smart device. A smart device is an electronic or electromechanical device, generally connected to other devices or networks via different wireless protocols such as Bluetooth, Zigbee, NFC, Wi-Fi, Li-Fi, or 5G that can operate to some extent interactively and autonomously, e.g., a smart television or home assistant device, virtual/augmented reality system, e.g., a head-mounted display, or another electronic device capable of executing a set of instructions (sequential or otherwise) that specify action(s) to be taken by the computer system 700.

While the main memory 706, non-volatile memory 710, and storage medium 726 (also called a “machine-readable medium”) are shown to be a single medium, the term “machine-readable medium” and “storage medium” should be taken to include a single medium or multiple media (e.g., a centralized/distributed database and/or associated caches and servers) that store one or more sets of instructions 728. The term “machine-readable medium” and “storage medium” shall also be taken to include any medium that is capable of storing, encoding, or carrying a set of instructions for execution by the computer system 700.

In general, the routines executed to implement the embodiments of the disclosure can be implemented as part of an operating system or a specific application, component, program, object, module, or sequence of instructions (collectively referred to as “computer programs”). The computer programs typically include one or more instructions (e.g., instructions 704, 708, 728) set at various times in various memory and storage devices in a computer device. When read and executed by the one or more processors 702, the instruction(s) cause the computer system 700 to perform operations to execute elements involving the various aspects of the disclosure.

Moreover, while embodiments have been described in the context of fully functioning computer devices, those skilled in the art will appreciate that the various embodiments are capable of being distributed as a program product in a variety of forms. The disclosure applies regardless of the particular type of machine or computer-readable media used to actually effect the distribution.

Further examples can include machine-readable storage media, machine-readable media, or computer-readable media include recordable-type media such as volatile and non-volatile memory devices 710, floppy and other removable disks, hard disk drives, optical discs (e.g., Compact Disc Read-Only Memory (CD-ROMS), Digital Versatile Discs (DVDs)), and transmission-type media such as digital and analog communication links.

The network adapter 712 enables the computer system 700 to mediate data in a network 714 with an entity that is external to the computer system 700 through any communication protocol supported by the computer system 700 and the external entity. The network adapter 712 can include a network adapter card, a wireless network interface card, a router, an access point, a wireless router, a switch, a multilayer switch, a protocol converter, a gateway, a bridge, a bridge router, a hub, a digital media receiver, and/or a repeater.

The network adapter 712 can include a firewall that governs and/or manages permission to access proxy data in a computer network and tracks varying levels of trust between different machines and/or applications. The firewall can be any number of modules having any combination of hardware and/or software components able to enforce a predetermined set of access rights between a particular set of machines and applications, machines and machines, and/or applications and applications (e.g., to regulate the flow of traffic and resource sharing between these entities). The firewall can additionally manage and/or have access to an access control list that details permissions including the access and operation rights of an object by an individual, a machine, and/or an application, and the circumstances under which the permission rights stand.

The functions performed in the processes and methods can be implemented in differing order. Furthermore, the outlined steps and operations are only provided as examples, and some of the steps and operations can be optional, combined into fewer steps and operations, or expanded into additional steps and operations without detracting from the essence of the disclosed embodiments.

The techniques introduced here can be implemented by programmable circuitry (e.g., one or more microprocessors), software and/or firmware, special-purpose hardwired (i.e., non-programmable) circuitry, or a combination of such forms. Special-purpose circuitry can be in the form of one or more application-specific integrated circuits (ASICs), programmable logic devices (PLDs), or field-programmable gate arrays (FPGAs).

The description and drawings herein are illustrative and are not to be construed as limiting. Numerous specific details are described to provide a thorough understanding of the disclosure. However, in certain instances, well-known details are not described in order to avoid obscuring the description. Further, various modifications can be made without deviating from the scope of the embodiments.

The terms used in this specification generally have their ordinary meanings in the art, within the context of the disclosure, and in the specific context where each term is used. Certain terms that are used to describe the disclosure are discussed above, or elsewhere in the specification, to provide additional guidance to the practitioner regarding the description of the disclosure. For convenience, certain terms can be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way. One will recognize that “memory” is one form of a “storage” and that the terms can on occasion be used interchangeably.

Consequently, alternative language and synonyms can be used for any one or more of the terms discussed herein, nor is any special significance to be placed upon whether or not a term is elaborated or discussed herein. Synonyms for certain terms are provided. A recital of one or more synonyms does not exclude the use of other synonyms. The use of examples anywhere in this specification, including examples of any term discussed herein, is illustrative only and is not intended to further limit the scope and meaning of the disclosure or of any exemplified term. Likewise, the disclosure is not limited to various embodiments given in this specification.

1. A computer-implemented method for implementing an architecture for a smart building, comprising:
receiving, by one or more computer processors of a hub of the smart building, speech input from a smart speaker,
wherein the speech input describes a plurality of asynchronous events associated with a plurality of smart devices in the smart building, and
wherein the hub is connected to a cloud Web Application Messaging Protocol (WAMP) router located in a cloud;
converting the plurality of asynchronous events to at least one of a trigger, a condition, or an action to be performed by at least one smart device of the plurality of smart devices;
generating an automated flow for controlling at least one adapter in the smart building from the at least one of the trigger, the condition, or the action,
wherein the at least one adapter operates the at least one smart device, and
wherein the at least one smart device corresponds to at least one node in the automated flow;
determining that a third-party device is installed in the smart building;
responsive to determining that the third-party device is installed:
generating a new adapter for the third-party device; and
generating a new node corresponding to the third-party device in the automated flow; and
operating the at least one smart device and the third-party device using at least one microservice to issue remote procedure calls (RPCs) from the hub via the at least one adapter and the new adapter to the at least one smart device and the third-party device over a hub WAMP router in accordance with the automated flow by referencing the new node and the at least one node while obviating communication between the hub and the cloud.

2. The computer-implemented method of claim 1, comprising:
preventing a first adapter operating a first smart device from communicating with a second adapter operating a second smart device of the smart building.

3. The computer-implemented method of claim 1, wherein the automated flow is generated using a visual programming language, and
wherein the method comprises:
generating a graphical representation of the automated flow for display to a user on a graphical user interface (GUI) of the smart building, wherein the GUI is displayed on an electronic screen of the hub.

4. The computer-implemented method of claim 1, comprising:
receiving text or graphical input from a user input device communicably coupled to the hub,
wherein the text or graphical input references a first smart device; and
modifying a portion of the automated flow corresponding to the first smart device.

5. The computer-implemented method of claim 1, wherein operating the at least one smart device and the third-party device obviates use of an Internet connection to the Hub.

6. The computer-implemented method of claim 1, wherein the at least one microservice uses publish/subscribe messaging from the hub via the at least one adapter and the new adapter to the at least one smart device and the third-party device while obviating communication between the hub and the cloud.

7. The computer-implemented method of claim 1, comprising:
adding the at least one adapter, the at least one smart device, and the at least one microservice to a registry database; and
generating create, read, update and delete (CRUD) operations of the registry database via the RPCs.

8. A computer-implemented hub comprising:
one or more computer processors; and
a non-transitory, computer-readable storage medium storing instructions, which when executed by at least one of the one or more computer processors cause the computer-implemented hub to:
receive information describing a plurality of asynchronous events associated with a plurality of smart devices in a smart building;
convert the plurality of asynchronous events to at least one of a trigger, a condition, or an action to be performed by at least one smart device of the plurality of smart devices;
generate an automated flow for controlling at least one adapter in the smart building from the at least one of the trigger, the condition, or the action;
determine that a third-party device is installed in the smart building;
responsive to determining that the third-party device is installed:
generate a new adapter for the third-party device; and
generate a new node corresponding to the third-party device in the automated flow; and
operate the at least one smart device and the third-party device in accordance with the automated flow.

9. The computer-implemented hub of claim 8, wherein the computer-implemented hub is connected to a cloud Web Application Messaging Protocol (WAMP) router located in a cloud.

10. The computer-implemented hub of claim 8, wherein the at least one adapter operates the at least one smart device, and
wherein the at least one smart device corresponds to an existing node in the automated flow.

11. The computer-implemented hub of claim 8, wherein the at least one smart device and the third-party device are operated using at least one microservice to issue remote procedure calls (RPCs) from the computer-implemented hub via the at least one adapter and the new adapter to the at least one smart device and the third-party device over a hub WAMP router.

12. The computer-implemented hub of claim 8, wherein the at least one smart device and the third-party device are operated by referencing the new node and the at least one node while obviating communication between the hub and the cloud.

13. The computer-implemented hub of claim 8, wherein the instructions cause the computer-implemented hub to:
prevent a first adapter operating a first smart device from communicating with a second adapter operating a second smart device of the smart building.

14. The computer-implemented hub of claim 8, wherein the automated flow is generated using a visual programming language, and
wherein the instructions cause the computer-implemented hub to:
generate a graphical representation of the automated flow for display to a user on a graphical user interface (GUI) of the smart building,
wherein the GUI is displayed on an electronic screen of the computer-implemented hub.

15. A non-transitory, computer-readable storage medium storing instructions, which when executed by one or more computer processors cause the one or more computer processors to:
generate an automated flow for controlling at least one adapter in a smart building from at least one of a trigger, a condition, or an action,
wherein the at least one adapter operates at least one smart device, and
wherein the at least one smart device corresponds to at least one node in the automated flow;
determine that a third-party device is installed in the smart building;
responsive to determining that the third-party device is installed:
generate a new adapter for the third-party device; and
generate a new node corresponding to the third-party device in the automated flow; and
operate the at least one smart device and the third-party device using at least one microservice to issue remote procedure calls (RPCs) from a hub of the smart building via the at least one adapter and the new adapter to the at least one smart device and the third-party device over a hub Web Application Messaging Protocol (WAMP) router in accordance with the automated flow by referencing the new node and the at least one node while obviating communication between the hub and a cloud.

16. The non-transitory, computer-readable storage medium of claim 15, wherein the instructions cause the one or more computer processors to:
receive information describing a plurality of asynchronous events associated with a plurality of smart devices in the smart building,
wherein the hub is connected to a cloud WAMP router located in the cloud.

17. The non-transitory, computer-readable storage medium of claim 16, wherein the instructions cause the one or more computer processors to:
convert the plurality of asynchronous events to the at least one of the trigger, the condition, or the action,
wherein the action is to be performed by the at least one smart device.

18. The non-transitory, computer-readable storage medium of claim 15, wherein the instructions cause the one or more computer processors to:
prevent a first adapter operating a first smart device from communicating with a second adapter operating a second smart device of the smart building.

19. The non-transitory, computer-readable storage medium of claim 15, wherein the automated flow is generated using a visual programming language, and
wherein the instructions cause the one or more computer processors to:
generate a graphical representation of the automated flow for display to a user on a graphical user interface (GUI) of the smart building, wherein the GUI is displayed on an electronic screen of the hub.

20. The non-transitory, computer-readable storage medium of claim 15, wherein the instructions cause the one or more computer processors to:
receiving text or graphical input from a user input device communicably coupled to the hub,
wherein the text or graphical input references the first smart device; and
modifying a portion of the automated flow corresponding to the first smart device.

21.-37. (canceled)
